(19) United States
(12) Patent Application Publication
(10) Pub. No.: US 2009/0081862 A1
(43) Pub. Date: Mar. 26, 2009

(54) AIR GAP STRUCTURE DESIGN FOR ADVANCED INTEGRATED CIRCUIT TECHNOLOGY

(75) Inventors: Hsien-Wei Chen, Sinying City (TW); Hao-Yi Tsai, Hsinchu City (TW); Shin-Puu Jeng, Hsinchu (TW); Benson Liu, Taipei City (TW)

Correspondence Address: DUANE MORRIS LLP (TSMC);IP DEPARTMENT, 30 SOUTH 17TH STREET, PHILADELPHIA, PA, 19103-4196, US

(73) Assignee: TAIWAN SEMICONDUCTOR MANUFACTURING CO., LTD., Hsin-Chu (TW)

(21) Appl. No.: 11/860,122

(22) Filed: Sep. 24, 2007

(51) Int. Cl. H01L 21/4763

(52) U.S. Cl. 438/618; 257/E21.495

(57) ABSTRACT

A method for forming air gaps between interconnect structures in semiconductor devices provides a sacrificial layer formed over a dielectric and within openings formed therein. The sacrificial layer is a blanket layer that is converted to a material that is consumable in an etchant composition that the dielectric material and a subsequently formed interconnect material are resistant to. After the interconnect material is deposited a planarized surface including portions of the dielectric material, vertical sections of the converted material and portions of the interconnect material is produced. The etchant composition then removes the converted material thereby forming voids. A capping layer is formed over the structure resulting in air gaps. A sidewall protection layer may be optionally formed between the interconnect structure and the sacrificial material. In some embodiments an ARC layer may be formed over the dielectric and form part of the planar surface.

### FIELD OF THE INVENTION

The present invention is related most generally to semiconductor device fabrication, and more specifically to interconnect structures and reducing capacitance between interconnect lines.

### BACKGROUND

As, the semiconductor industry migrates to 90 nanometer and smaller technologies, the minimum distance between adjacent inner connect lines grows smaller. Inter-level dielectric materials (ILD) such as silicon oxide are being replaced by low-k dielectric materials, to reduce the capacitance between nearby interconnect lines. At the 32 and 45 nanometer nodes, the capacitance problem is even more acute. Typical methods to reduce capacitance between interconnect lines include using an ILD (Inter-Layer-Dielectric) or IMD (Inter Metal Dielectric) material with a lower k value, such as FSG, carbon-doped silicon oxide (e.g., BLACK DIAMOND® produced by the Applied Materials Company) and extreme low-k (ELK) dielectrics having a k value less than 2.5, to reduce interconnect capacitance.

Dielectric materials with reduced k have a lower mechanical strength. There are many reliability issues when using ELK dielectrics, in particular packaging problems. ELK film strength is about 50% weaker than low-K. When ELK and ultra low-k (ELK) materials are used, the thermal mismatch between the die and the package substrate can cause cracking and/or delamination of the ILD material. ELK also has a high cost. Integration of ELK requires a very complicated process flow (e.g. pore sealing, UV/e-beam cure, and the like), which increases cost and cycle time. ELK has a low thermal conductivity (<0.2 W/m-C), which impedes thermal dissipation and causes electromigration and other thermal related reliability problems. ELK thus has a number of associated shortcomings.

U.S. Patent Application Publication Nos. US 2005/0074961 and 2005/0074960 describe methods for the production of air gaps in a semiconductor device. Air is used for its dielectric and insulation properties. The formation of air gaps is accomplished, in part, by chemically and/or mechanically changing the properties of a first dielectric layer locally, such that at least part of the first dielectric layer is converted locally and becomes etchable by a first etching substance. The local conversion of the dielectric material may be achieved during anisotropic etching of the material in oxygen-containing or fluorine-containing plasma or ex-situ by performing an oxidizing step, e.g., al UV/ozone treatment or supercritical carbon dioxide with addition of an oxidizer. Formation of air gaps is achieved after creation of conductive lines and, alternatively, a barrier layer by a first etching substance. The air gaps are formed in a dual damascene structure, near the vias and/or the trenches of the damascene structure, and these air gaps lower the capacitance between adjacent interconnect structures and represent an attractive alternative to the use of ELK materials.

Improved methods of reducing capacitance between interconnect lines are desired.

### SUMMARY OF THE INVENTION

To address these and other needs and in view of its purposes, the present invention provides a method for forming a semiconductor device with, air gaps. The air gaps may be advantageously disposed adjacent interconnect structures.

The method includes forming a semiconductor structure on a substrate. The semiconductor structure includes openings in at least a material layer thereof. The material layer is resistant to an etchant composition. The method further includes depositing a blanket film over the material layer. The blanket film includes vertical sections along sidewalls of the openings as well as horizontal sections. The method then provides for converting substantially all of the blanket film to a converted material removable in the etchant composition, removing the horizontal sections and filling the openings with an interconnect material that is resistant to the etchant composition to produce a structure having an upper surface comprising portions of at least the material layer, the vertical sections of the converted material, and the interconnect material.

According to another aspect, the present invention provides a method for forming a semiconductor device with air gaps. The method includes forming a semiconductor structure on a substrate, the semiconductor structure including a composite material layer of an ARC layer formed over a dielectric layer, and openings extending through at least the composite material layer. The composite material layer is resistant to an etchant composition. The method further includes depositing a blanket film over the material layer, the blanket film including vertical sections along sidewalls of the opening's, and horizontal sections. Substantially all of the blanket film is converted to a converted oxide material removable in the etchant composition and the horizontal sections are removed using fan anisotropic etching process that leaves the vertical sections substantially intact. The openings are then filled with an interconnect material that is resistant to the etchant composition thereby producing a structure having an upper surface comprising at least the composite material layer, the vertical sections of the converted material and the interconnect material. The method further provides for etching with the etchant composition, thereby removing the vertical sections of the converted material and creating voids. A capping layer is then formed over the upper surface and over the voids but not filling the voids, thereby creating air gaps in the voids.

### BRIEF DESCRIPTION OF THE DRAWING

The present invention is best understood from the following detailed description when read in conjunction with the accompanying drawing. It is emphasized that, according to common practice, the various features of the drawing are not necessarily to scale. On the contrary, the dimensions of the various features are arbitrarily expanded or reduced for clarity. Like numerals denote like features throughout the specification and drawing.

FIGS. 1A-1I are cross-sectional views showing a sequence of processing operations according to one exemplary embodiment of the invention;

FIGS. 2A-2C are cross-sectional views showing a process sequence illustrating another exemplary embodiment of the invention; and

FIGS. 3A-3H are cross-sectional views of a process sequence that illustrates additional aspects of the invention.

### DETAILED DESCRIPTION

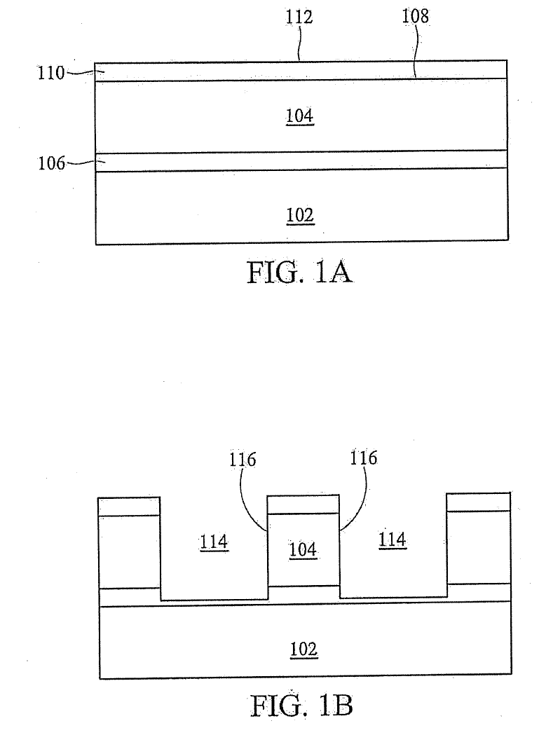

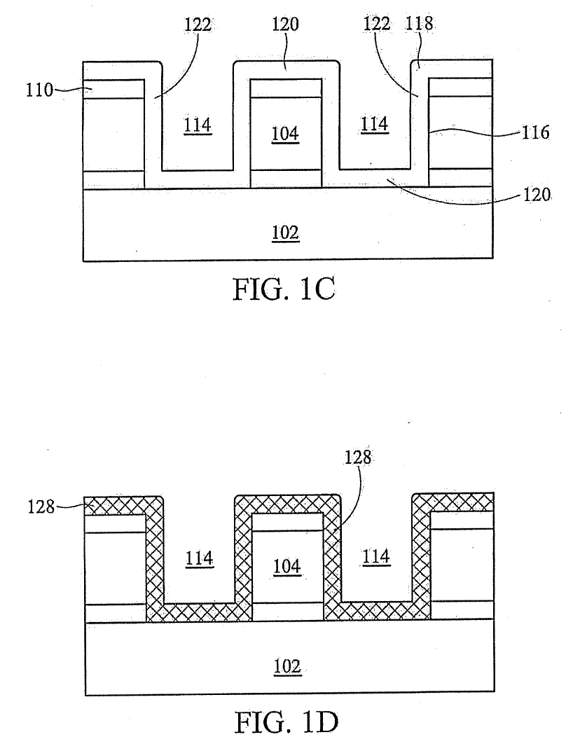

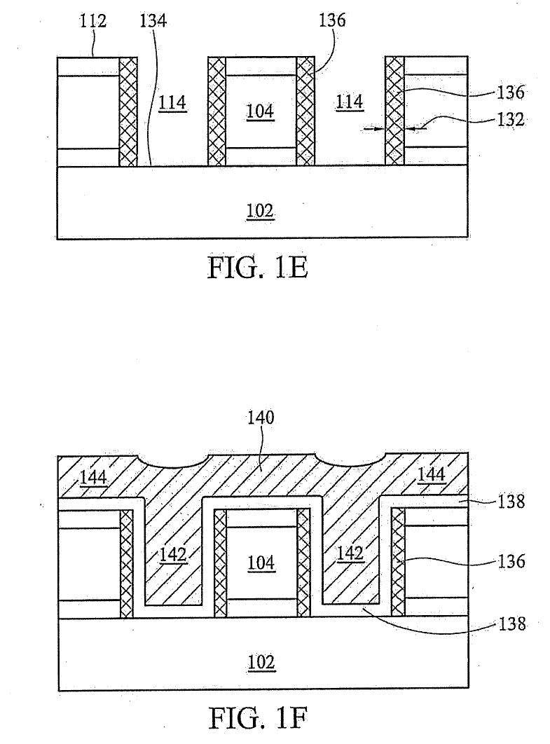

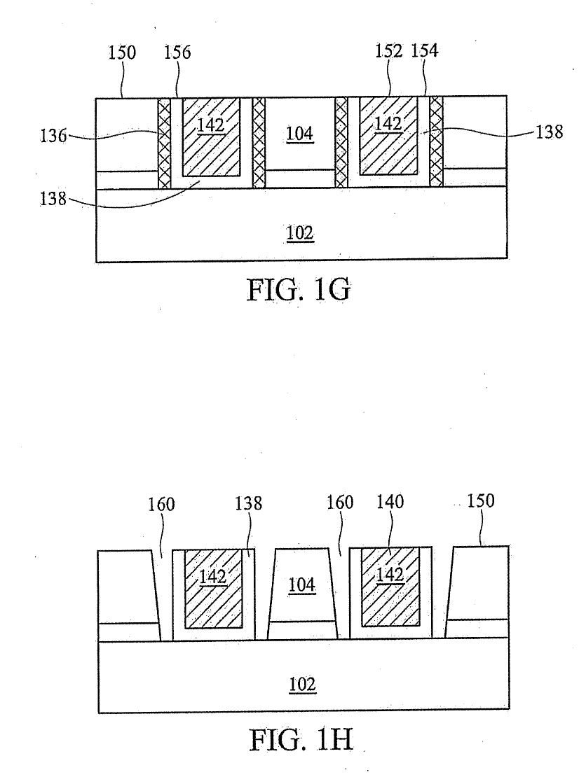

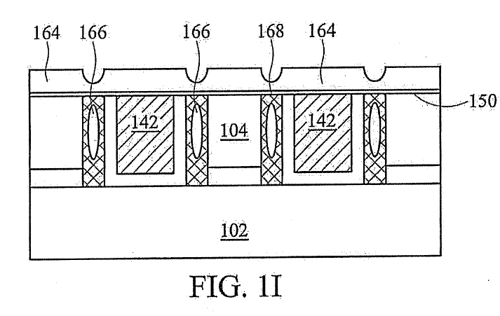

FIG. 1A shows substrate 102 and material layer 104 formed thereover. Layer 106 is interposed therebetween and may be an etch stop layer in one exemplary embodiment. Layer 106 may represent any of various other films used in semiconductor device fabrication, in other exemplary embodiments. Top layer 110 is formed over upper surface 108 of material layer 104. Top layer 110 includes upper surface 112 and may be an anti-reflective coating, ARC, or top layer 110 may be SiON or SiC or other suitable material with CH₃ functional groups. Material layer 104 may be a dielectric film and material layer 104 may advantageously be a low-k, k=2.9-2.5, dielectric film. Substrate 102 may be any of various suitable substrates used in the semiconductor manufacturing industry such as silicon.

Conventional means are then used to form openings 114 shown in FIG. 1B. Openings 114 extend through top layer 110, material layer 104 and layer 106 and are bounded by sidewalls 116. In one exemplary embodiment, openings 114 may represent vias or trenches. In one embodiment, openings 114 may be trenches that are parallel one another.

Now turning to FIG. 1C, sacrificial layer 118 is formed over the structure shown in FIG. 1B. Sacrificial layer 118 includes horizontal sections 120 formed on the bottom of openings 114 and over upper surface 112 of top layer 110. Sacrificial layer 118 is a blanket material and also includes vertical sections 122 formed along sidewalls 116 of openings 114. Sacrificial layer 118 may be SiOC, SiC, FSG (fluoro-silicate glass), Black Diamond® (carbon-doped silicon oxide) supplied by Applied Materials Company or various other suitable materials with higher CH₃ functional groups. Sacrificial layer 118 may be low-k dielectric material with k=2.9-2.5.

Sacrificial layer 118 of FIG. 1C is then converted to converted layer 128 shown in FIG. 1D. In one exemplary embodiment, the conversion process may constitute an oxidation process such as ashing. The ashing conditions are chosen to substantially completely oxidize sacrificial layer 118 and produce converted material 128 which is removable using an etchant composition that does not attack material layer 104 or top layer 110. The conversion process and degree of oxidation is also chosen in conjunction with the interconnect material to be used because one aspect of the invention is that, after conversion, converted material 128 will be removable using the etchant composition which will not remove the other exposed materials such as material layer 104, top layer 110 and the subsequently formed interconnect material or materials. The processing, conditions are chosen to substantially completely convert the film using a plasma oxidation process. The ashing conditions are dependent on the tool and program settings and in one exemplary embodiment, the processing conditions may include a process time ranging from about 30 seconds to about 2 minutes, a chamber pressure ranging from about 10 to about 30 millitor, an upper RF power ranging from about 500-1500 watts, a lower RF power ranging from about 100 to about 300 watts and an O₂ flow of about 200-400 sccm but various other suitable processing conditions may be used in order to effectuate Ma substantially complete conversion of sacrificial layer 118 to converted material 128.

FIG. 1E shows the structure of FIG. 1D after horizontal portions of converted material 128 have been removed by an anisotropic etch process that spatially selectively removes the horizontal portions only. Various suitable anisotropic etching operations may be used. Upper surface 112 and bottom surface 134 of opening 114 are now exposed following an etching operation that leaves vertical sections 136 substantially intact. Vertical sections 136 of converted material 128 may include a thickness 132 ranging from about 30-60 angstroms in one exemplary embodiment but other thicknesses may be used in other exemplary embodiments and will depend upon other device dimensions.

FIG. 1F shows the structure of FIG. 1E after barrier layer 138 and conductive material 140 are successively formed over the structure of FIG. 1E, barrier layer 138 and conductive material 140 together filling former openings 114. Barrier layer 138 may be various suitable barrier materials such as Ta, TaN, TiN or other conventional barrier materials and in other embodiments, a barrier layer may not be used. Conductive material 140 may be formed by electroplating or electro-chemical plating, ECP, but other suitable methods may also be used. Conductive material 140 may be copper in one advantageous embodiment, but other conductive materials may be used in other exemplary embodiments. Conductive material 140 includes interconnect portions 142 and upper portions 144 that are formed over material layer 104 and top layer 110. In other exemplary embodiments, additional layers may be used to constitute, the interconnect structure.

Next, a planarization process such as CMP, chemical mechanical polishing, is performed on the structure of FIG. 1F to produce the structure illustrated in FIG. 1G. The planarization process removes upper portions 144 of conductive material 140 as well as the portions of barrier layer 138 and top layer 110 that lie above material layer 104, producing planar top surface. 150 which includes upper surface 108 of material layer 104, planar surface 152 of interconnect portion 142 of conductive material 140, edge 154 of barrier layer 138 and edge 156 of converted material 128. In the cross-sectional view, interconnect portions 142 may represent adjacent parallel interconnect lines that run orthogonal to the plane of the drawing sheet.

FIG. 1H shows the figure of FIG. 1G after a selective etching process has been carried out to selectively remove converted portions 128 that were illustrated in FIG. 1G, to produce voids 160, while substantially leaving the remainder of the structure intact. Various etchant compositions may be used and chosen in conjunction with converted material 128 to be etched and barrier layer 138, conductive material 140 and material layer 104 which are to be resistant to the etchant composition. The etchant composition may include HF and various other components such as CH₃COOH and/or NH₄F to produce an etching 'selectivity in which converted material 128 (see FIG. 1G) etches as much as 100 times more quickly than barrier layer 138, conductive material 140 and material layer 104. The selective etch process may be a wet HF dip.

A capping layer is then formed over the structure shown in FIG. 1H, to produce air gaps as shown in FIG. 1I. Capping layer 164 is formed over planar surface 150 but the deposition conditions are controlled so that capping layer 164 does not completely fill voids 160 of FIG. 1H. Rather, the deposition process is controlled to produce air gaps 166, although portions 168 of the capping material may be deposited within voids 160. In one exemplary embodiment, air gaps 166 may include a width of about 110-170 angstroms, but various other widths ranging from a few to hundreds of angstroms may be achieved depending on the width of voids 160 and the conditions of the deposition process used to form capping layer 164. In one exemplary embodiment, capping layer 164 may be SiC, but other materials, dielectric or otherwise, may alternatively be used. In one exemplary embodiment, a PECVD (plasma enhanced chemical vapor deposition) process with poor filling properties may be used to form capping layer 164 but other processes may be used in other exemplary embodiments. Process conditions are chosen such that voids with high aspect ratios such as in the range of about 1:5 to 1:10 will not be completely filled by the deposition process resulting in air gaps 166. Various semiconductor fabrication processes may now be carried out on the structure shown in FIG. 1I to form various semiconductor devices. Capacitance between adjacent conductive interconnect structures represented by filler portions 142, is reduced due to air gaps 166. Air gaps 166 extend along sides of the conductive interconnect structures and between adjacent conductive interconnect structures.

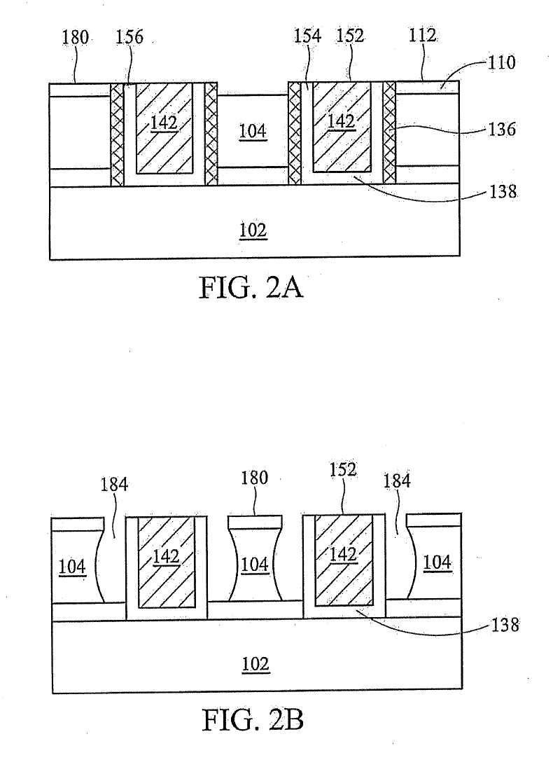

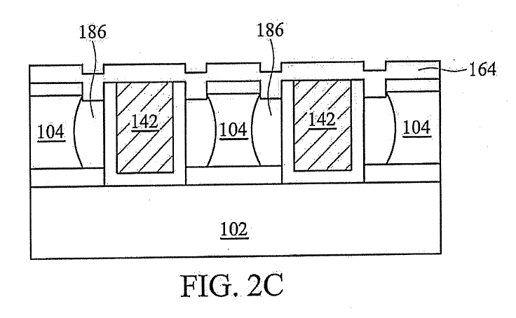

FIGS. 2A-2C illustrate another exemplary embodiment of the invention. FIG. 2A illustrates a structure produced after the structure of FIG. 1F is planarized using a polishing operation that terminates upon top layer 110 and differs from the structure shown in FIG. 1G in which top layer 110 had been removed by the polishing operation. In FIG. 2A, at least part of top layer 110 is unremoved. Referring to FIG. 2A, planar top surface 180 includes upper surface 112 of top layer 110 as well as planar surface 152 of interconnect portion 142 of conductive material 140, edge 154 of barrier layer 138 and edge 156 of converted material 128. In other words, material layer 104 is not exposed. The selective etching process described above is then performed upon the structure of FIG. 2A to selectively remove substantially only converted material 128 and produce the structure shown in FIG. 2B. Voids 184 are formed.

Capping layer 164 is formed over the structure of FIG. 2B to produce the structure of FIG. 2C which includes air gaps 186.

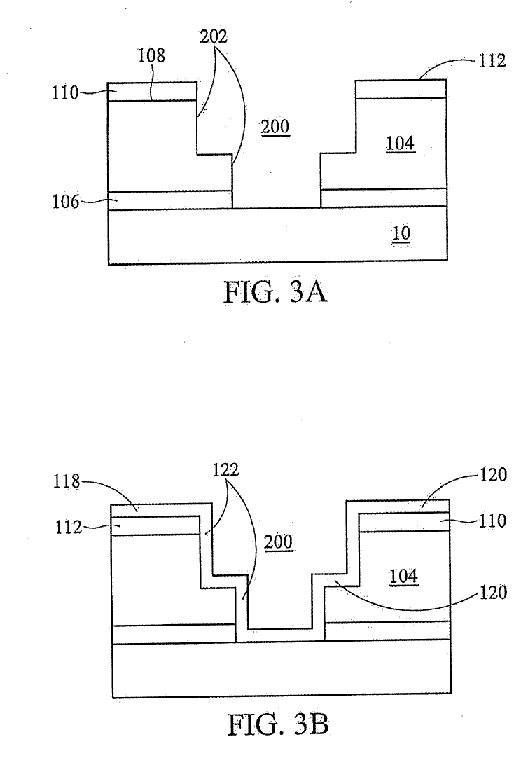

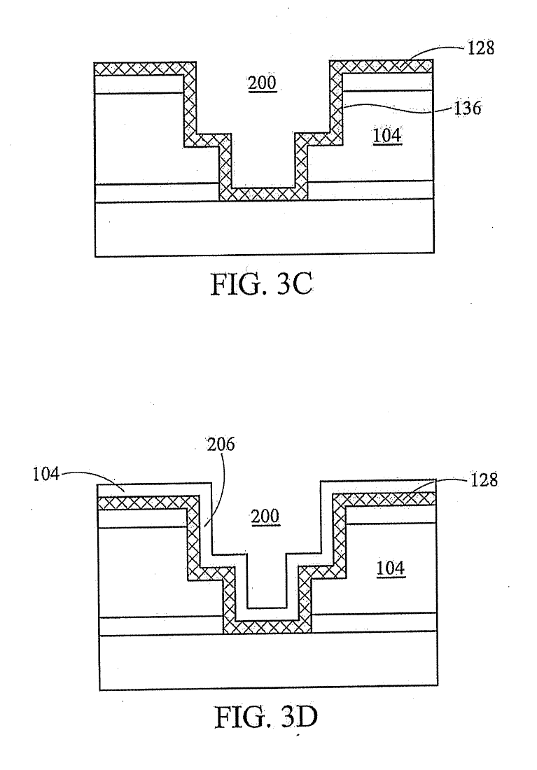

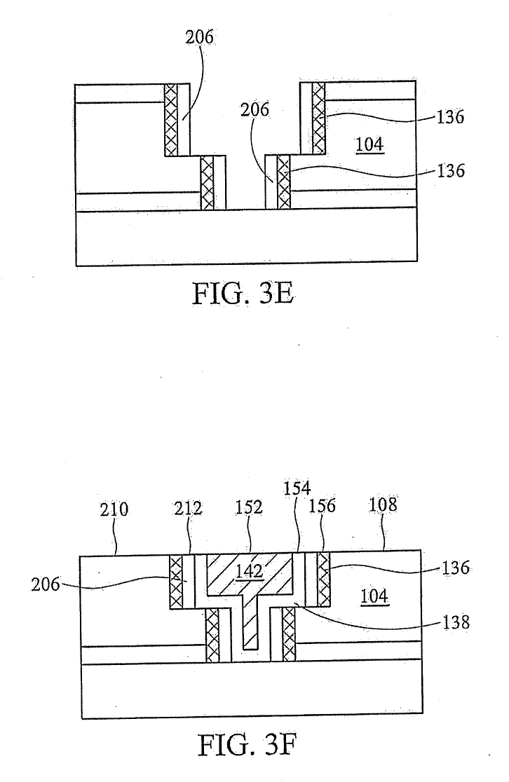

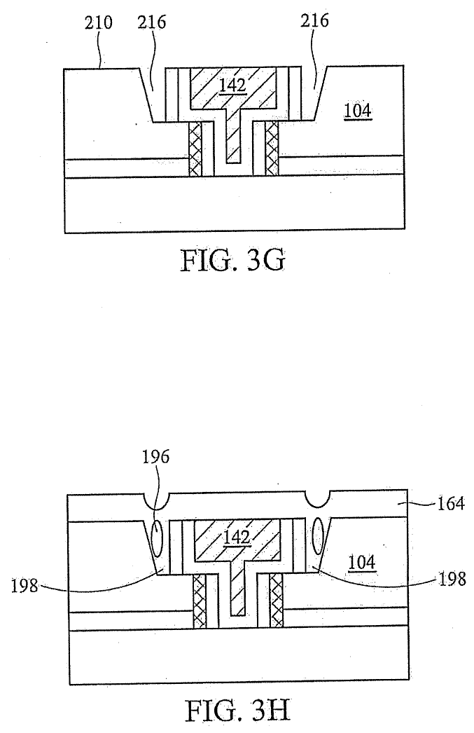

FIGS. 3A-3G illustrate further aspects of the invention. Like reference numbers denote like features throughout the specification. For brevity, like aspects of the sequence of process operations described in conjunction with FIGS. 1A-1I, will not be repeated with respect to FIGS. 3A-3H, other than to highlight additional aspects of the invention.

In FIG. 3A, opening 200 is a dual damascene opening that includes staggered sidewalls 202 but still other openings may be used in other exemplary embodiments. FIG. 3B shows sacrificial layer 118 formed over upper surface 112 and lining opening 200. Sacrificial layer 118 includes multiple horizontal sections 120 and vertical sections 122.

Sacrificial layer 118 is converted to converted material 128 including vertical sections 136, as shown in FIG. 3C.

Now referring to FIG. 3D, protection layer 204 is formed over the structure illustrated in FIG. 3C. Protection layer 204 includes vertical sections 206 and will generally be a high dielectric constant material that may have a dielectric constant ranging from 2.5-5.5. Protection layer 204 may include a thickness of about 50-200 angstroms in one exemplary embodiment, but other thicknesses may be used in other exemplary embodiments. Good candidates for use as protection layer 204 will generally include a high Young's modulus to increase electromigration reliability and a lower dielectric k-value, but these two properties are generally conflicting. In various exemplary embodiments, protection layer may be SiC, FSG, SiO₂, SiON, SiOC, Black Diamond® supplied by Applied Materials Company, or other suitable materials. Protection layer 204 is chosen to be resistant to the etchant composition that will remove converted material 128 to form voids.

FIG. 3E shows the structure of FIG. 3D after an anisotropic etching process spatially selectively removes horizontal portions of both protection layer 204 and converted material 128. Sidewalls 202 now include both vertical sections 206 of protection layer 204 and vertical sections 136 of converted material 128.

CMP or another polishing or planarization process is then carried out to produce planar top surface 210 which includes upper surface 108-of material layer 104 as well as upper edge 212 of vertical section 206 of protection layer 204 and planar surface 152 of interconnect portion 142 of conductive material 140, planar edge 154 of barrier material 138 and planar edge 156 of vertical sections 136 of converted material 128. According to another exemplary embodiment, the polishing operation may be terminated with at least some thickness of top layer 110 still in place over material layer 104.

Now turning to FIG. 3G, the etchant composition is then used to produce voids 216 by selectively etching converted material 128 but not vertical sections 206 of protection layer 204 or the other materials As*shown in FIG. 3H, capping layer 164 is formed over planar top surface 210 to provide air gaps 196, although portions 198 of capping material 164 may be present in voids 216. Air gaps 196 are adjacent and extend along the interconnect structure formed by interconnect portion 142 of conductive material 140.

The preceding merely illustrates the principles of the invention. It will thus be appreciated that those skilled in the art will be able to devise various arrangements which, although not explicitly described or shown herein, embody the principles of the invention and are included within its spirit and scope. Furthermore, all examples and conditional language recited herein are principally intended expressly to be only for pedagogical purposes and to aid the reader in understanding the principles of the invention and the concepts contributed by the inventors to furthering the art, and are to be construed as being without limitation to such specifically recited examples and conditions. Moreover, all statements herein reciting principles, aspects, and embodiments of the invention, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

This description of the exemplary embodiments is intended to be read in connection with the figures of the accompanying drawing, which are to be considered part of the entire written description. In the description, relative terms such as “lower,” “upper,” “horizontally,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

What is claimed is:

1. A method for forming a semiconductor device with air gaps, said method comprising:
forming a semiconductor structure on a substrate, said semiconductor structure including openings in at least a material layer thereof, said material layer resistant to an etchant composition;
depositing a blanket film over said material layer, said blanket film including vertical sections along sidewalls of said openings, and horizontal sections;
converting substantially all of said blanket film to a converted material removable in said etchant composition;
removing said horizontal sections; and
filling said openings with an interconnect material that is resistant to said etchant composition and providing a structure having an upper surface comprising portions of at least said material layer, said vertical sections and said interconnect material.

2. The method as in claim 1, wherein said horizontal sections are disposed over said material layer and along bottom portions of said openings and said removing, said horizontal sections comprises anisotropically etching said horizontal sections while leaving said vertical sections substantially intact.

3. The method as in claim 1, further comprising, after said providing a structure, etching with said etchant composition to selectively remove said vertical sections of said converted material thereby creating Voids.

4. The method as in claim 3, further comprising, after said etching, forming a capping layer over said upper surface and over said voids thereby forming air gaps in said voids.

5. The method as in claim 4, wherein said openings comprise parallel trenches, said interconnect material forms conductive interconnect lines in said trenches and said air gaps extend parallel to and between said trenches.

6. The method as in claim 1, further comprising, after said providing a structure, etching with said etchant composition to selectively remove said vertical sections of said converted material thereby creating voids, forming a capping layer over said upper surface and over said voids thereby forming air gaps in said voids, and wherein said openings comprise parallel trenches, said interconnect material forms conductive interconnect lines in said trenches and said air gaps are disposed between said trenches.

7. The method as in claim 1, wherein said, filling said openings comprises depositing said interconnect material filling said, openings and over said material layer, said providing comprises a chemical mechanical polishing (CMP) operation to form said upper surface, and said upper surface is planar.

8. The method as in claim 1, wherein said interconnect material comprises a barrier layer and copper.

9. The method as in claim 1, wherein said blanket film comprises SiC and said converting comprises ashing to oxidize said blanket film.

10. The method as in claim 1, wherein said blanket film comprises one of SiOC, FSG, Black Diamond®, and a further material with a CH₃ functional group.

11. The method as in claim. 1 wherein said converting Comprises converting said blanket film to an oxide.

12. The method as in claim 1, Wherein said openings in said at least an upper material layer comprise dual damascene openings.

13. The method as in claim 1, wherein said material layer is a low-k dielectric.

14. The method as in claim 1, further comprising forming a sidewall protection layer along at least one of said vertical sections prior to said removing and wherein said upper surface comprises at least a section of said sidewall protection layer.

15. The method as in claim 1, further comprising said semiconductor structure including at least one further material layer, said at least one further material layer being at least one of an ARC layer disposed over said material layer and resistant to said etchant composition, and an etch stop layer disposed below said material layer, and wherein said openings extend through said at least one further material layer.

16. The method as in claim 1, further comprising an ARC layer formed over said material layer and wherein:
said material layer comprises a dielectric layer;
said, openings further extend through said ARC layer;
said blanket film is deposited over said ARC layer;
said ARC layer is resistant to said etchant composition; and
said filling and providing include depositing said interconnect material over said ARC layer, removing portions of said interconnect material from over said material layer and removing said ARC, layer.

17. The method as in claim 1, wherein said material layer is a composite layer comprising an ARC layer formed over a dielectric layer.

18. The method as in claim 1, wherein said upper surface is planar and includes a top edge of said vertical sections.

19. A method for forming a semiconductor device with air gaps, said method comprising:
forming a semiconductor structure on a substrate, said semiconductor structure including a composite material layer of an ARC layer formed over a dielectric layer and openings extending through at least said composite material layer, said composite material layer being resistant to an etchant composition;
depositing a blanket film over said material layer and within said openings, said blanket film including vertical sections along sidewalls of said openings, and horizontal sections;
converting substantially all of said blanket film to a converted oxide material removable in said etchant composition;
removing said horizontal sections using an anisotropic etching process that leaves said vertical sections substantially intact;
filling said openings with an interconnect material that is resistant to said etchant composition and producing a structure having an upper surface comprising at least said composite material layer, said vertical sections of said converted material and said interconnect material;
etching with said etchant composition, thereby removing said vertical sections of said converted material and creating voids; and
forming a capping layer over said upper surface and over said voids, thereby creating air gaps in said voids.

20. The method as in claim 19, wherein said openings comprise parallel dual damascene trenches, said interconnect material comprises a barrier layer and conductive material, said filling further comprises forming said interconnect material over said composite material layer, and said producing comprises planarizing to remove portions of said interconnect material from over said composite material layer, said upper surface including portions of said barrier layer and said conductive material.
